(19) United States
(12) Patent Application Publication
(10) Pub. No.: US 2015/0355515 A1
(43) Pub. Date: Dec. 10, 2015

(54) PIXEL STRUCTURE, METHOD OF MANUFACTURING THE SAME, AND DISPLAY DEVICE

(71) Applicants: BOE Technology Group Co., Ltd., Beijing (CN); Beijing BOE Display Technology Co., Ltd., Beijing (CN)

(72) Inventors: Bo Feng, Beijing (CN); Yu Ma, Beijing (CN)

(21) Appl. No.: 14/486,258

(22) Filed: Sep. 15, 2014

(30) Foreign Application Priority Data
Jun. 10, 2014 (CN) 201410256849.5

(51) Int. Cl. G02F 1/1362; H01L 27/12; G02F 1/1368

(52) U.S. Cl. CPC G02F 1/136213; G02F 1/1368; G02F 1/136227; H01L 27/124; H01L 27/1259

(57) ABSTRACT

The present invention provides a pixel structure and a display device, the pixel structure comprises thin film transistors; a substrate, and common electrodes, a gate insulation layer, a passivation layer and pixel electrodes stacked in order on the substrate. The pixel structure further comprises electrically conductive electrodes located between the passivation layer and the gate insulation layer, and the electrically conductive electrodes are located within overlapped regions between the pixel electrodes and the common electrodes and electrically connected with the pixel electrodes, respectively. In the above pixel structure, the common electrode and both of the electrically conductive electrode and the pixel electrode form storage capacitors, so that there is only one film layer, that is, the gate insulation layer, between the pixel electrode and the common electrode, thereby reducing a distance between two parts forming the storage capacitor, increasing the storage capacitor, and improving display performance of the display device.

### CROSS-REFERENCE TO RELATED APPLICATION

This application claims the benefit of Chinese Patent Application No. 201410256849.5 filed on Jun. 10, 2014 in the State Intellectual Property Office of China, the whole disclosure of which is incorporated herein by reference.

### BACKGROUND OF THE INVENTION

1. Field of the invention

Embodiments of the present invention relates to display technique field, and in particular, to a pixel structure, a method of manufacturing the same, and a display device.

2. Description of the Related Art

A main pixel region of a liquid crystal display device comprises a plurality of pixel units arranged in an array, each of which comprises red, green and blue three sub-pixels.

A pixel structure of the liquid crystal display device may be classified into a single gate driven type, double-gate driven type, tri-gate driven type or the like based on driving modes. In the double-gate driven pixel structure, sub-pixels of three colors are driven by two gates simultaneously, and two adjacent sub-pixels share the same one data line, thereby enabling reduction in number of data driving chips and in manufacturing cost.

In the double-gate driven pixel structure, however, there are two film layers, that is, a gate insulation layer and a passivation layer, between a common electrode and a pixel electrode, resulting in a larger distance between the common electrode and the pixel electrode, and a smaller storage capacitor formed by the common electrode and the pixel electrode, which adversely affects display performance of the display device.

### SUMMARY OF THE INVENTION

The present invention provides a pixel structure and a display device, in order to increase the storage capacitor formed by the common electrode and the pixel electrode and to improve display performance of the display device.

In one aspect of embodiments of the present invention, there is provided a pixel structure, comprising: thin film transistors; a substrate, and common electrodes, a gate insulation layer, a passivation layer and pixel electrodes stacked in order on the substrate; and electrically conductive electrodes located between the passivation layer and the gate insulation layer, the electrically conductive electrodes being located within overlapped regions between the pixel electrodes and the common electrodes and electrically connected with the pixel electrodes, respectively.

In another aspect of embodiments of the present invention, there is provided a display device comprising the above pixel structure.

In yet another aspect of embodiments of the present invention, there is provided a method of manufacturing a pixel structure, comprising following steps:

forming a first pattern including common electrodes, gate lines, and gates of thin film transistors on a substrate by using a patterning process, wherein the gate lines are electrically connected with the gates respectively;

forming a gate insulation layer over the substrate by using a film deposition process after the step of forming the first pattern;

forming a second pattern including electrically conductive electrodes, data lines, sources and drains of the thin film transistors on the gate insulation layer by using a patterning process, wherein the data lines are electrically connected with the sources respectively;

forming a passivation layer over the substrate by using a film deposition process after forming the second pattern, and then forming via holes and pixel electrode contact holes in the passivation layer by using a patterning process; and

forming pixel electrodes on the passivation layer, so that the pixel electrodes are electrically connected with the electrically conductive electrodes respectively through the via holes and are electrically connected with the drains respectively through the pixel electrode contact holes.

### BRIEF DESCRIPTION OF THE DRAWINGS

The above and other features of the present invention will become more apparent by describing in detail exemplary embodiments thereof with reference to the accompanying drawings, in which:

FIG. 1 is a view showing a pixel structure provided according to embodiments of the present invention;

FIG. 2 is a view showing arrangement within a single grid of a pixel structure provided according to an exemplary embodiment of the present invention;

FIG. 3 is a sectional view of the pixel structure provided according to the exemplary embodiment of the present invention taken in an A-A′ direction in FIG. 2;

FIG. 4 is a sectional view of a prior art pixel structure taken in the A-A′ direction in FIG. 2; and

FIG. 5 is a view showing a distribution of via holes in the pixel structure provided according to embodiments of the present invention.

### DETAILED DESCRIPTION OF PREFERRED EMBODIMENTS OF THE INVENTION

Exemplary embodiments of the present invention will be described hereinafter in detail with reference to the attached drawings, wherein the like reference numerals refer to the like elements. The present invention may, however, be embodied in many different forms and should not be construed as being limited to the embodiment set forth herein; rather, these embodiments are provided so that the present invention will be thorough and complete, and will fully convey the concept of the disclosure to those skilled in the art.

Embodiments of the present invention provide a pixel structure, comprising: thin film transistors; a substrate, and common electrodes, a gate insulation layer, a passivation layer and pixel electrodes stacked in order on the substrate; and electrically conductive electrodes located between the passivation layer and the gate insulation layer, the electrically conductive electrodes being located within overlapped regions between the pixel electrodes and the common electrodes and electrically connected with the pixel electrodes, respectively.

In a pixel structure of prior arts, overlapped portions of the pixel electrode and the common electrode are often separated by the passivation layer and the gate insulation layer, resulting in that there is a larger distance between the pixel electrode and the common electrode, and a storage capacitor formed by the pixel electrode and the common electrode is smaller. In the pixel structure of the present invention, a storage capacitor is formed between both of the electrically conductive electrode and the pixel electrode, and the common electrode, so that there is only one film layer, that is, the gate insulation layer, between the pixel electrode and the common electrode, which reduces the distance between two parts forming the storage capacitor, thereby increasing the storage capacitor, and improving display performance of the display device.

Specifically, in the pixel structure in which the storage capacitor is formed between the common electrode and both of the electrically conductive electrode and the pixel electrode, the electrically conductive electrode is formed between the passivation layer and the gate insulation layer and is electrically connected with the pixel electrode, and also is overlapped with the common electrode, so as to form the storage capacitor, thus, the two parts forming the storage capacitor are a connection structure between the electrically conductive electrode and pixel electrode, and the common electrode, and a distance between the two parts is only equal to a film thickness of the gate insulation layer. Thus, the distance between the two parts forming the storage capacitor is reduced, thereby increasing the storage capacitor, and achieving effects of improving display performance of the display device.

The pixel structure according to the present embodiment will be described in detail hereafter by taking a double-gate driven pixel structure for example.

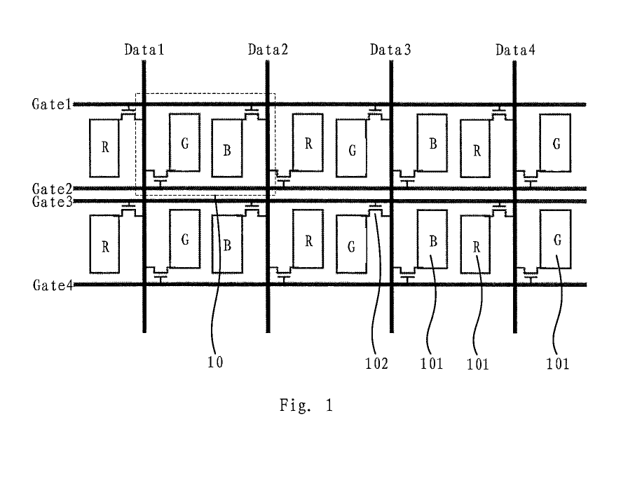

In this embodiment, the double-gate driven pixel structure is shown in FIG. 1 for illustration, in which a plurality of gate lines (such as gate lines Gate1˜Gate4 shown in the figure) in a first direction and a plurality of data lines (such as data lines Data1˜Data4 shown in the figure) in a second direction are crossed with respect to each other to form a plurality grids, and the first direction and the second direction may be, for example, perpendicular to each other. There are two sub-pixels 101 and two TFTs 102 within each grid, respective sub-pixels 101 are arranged in the first direction in order of red (R), green (G) and blue (B) colors, and pixels of the same color are arranged in the second direction. Among respective rows of sub-pixels arranged in the first direction, there are two gate lines between two adjacent rows of sub-pixels; among respective rows of sub-pixels arranged in the second direction, there is one data line between two adjacent rows of sub-pixels. The sub-pixels in the first direction are alternately connected with two gate lines, and two adjacent sub-pixels of the sub-pixels in the first direction which are located within two adjacent grids are connected with the same one data line. Thus, in such a double-gate driven pixel structure, number of the gate lines is twice that of the data lines.

It is noted that the grids as described above only indicate those within which sub-pixels 101 are arranged. Similar regions defined by, for example, Gate2, Gate3, Data1 and Data2 shown in FIG. 1 are not called as grids in this embodiment, since there is no sub-pixel arranged therein, and there is a smaller distance between two gate lines (such as Gate2 and Gate3) defining the similar regions.

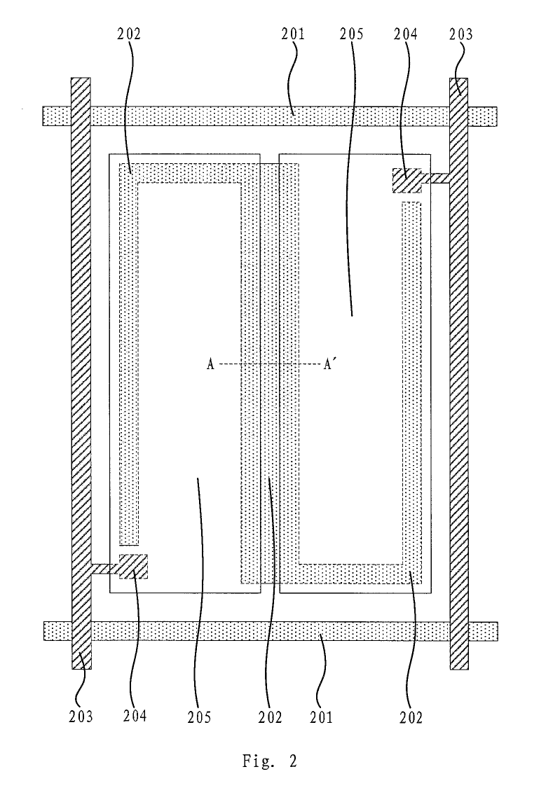

An arrangement within each grid (for example, a region 10 shown in FIG. 1) of the above double-gate driven pixel structure is illustratively shown in FIG. 2, and comprises: gate lines 201; gates (not shown) of thin film transistors 204 formed in the same layer as the gate lines 201; common electrodes 202 formed in the same layer as the gate lines and having fold line shapes; data lines 203; sources and drain (not shown) of the thin film transistors 204 formed in the same layer as the data lines 203, wherein the sources are electrically connected with the data lines 203 respectively; and two pixel electrodes 205 partially overlapped with the common electrodes 202, the drains of the thin film transistors 204 being electrically connected with the pixel electrodes 205 respectively.

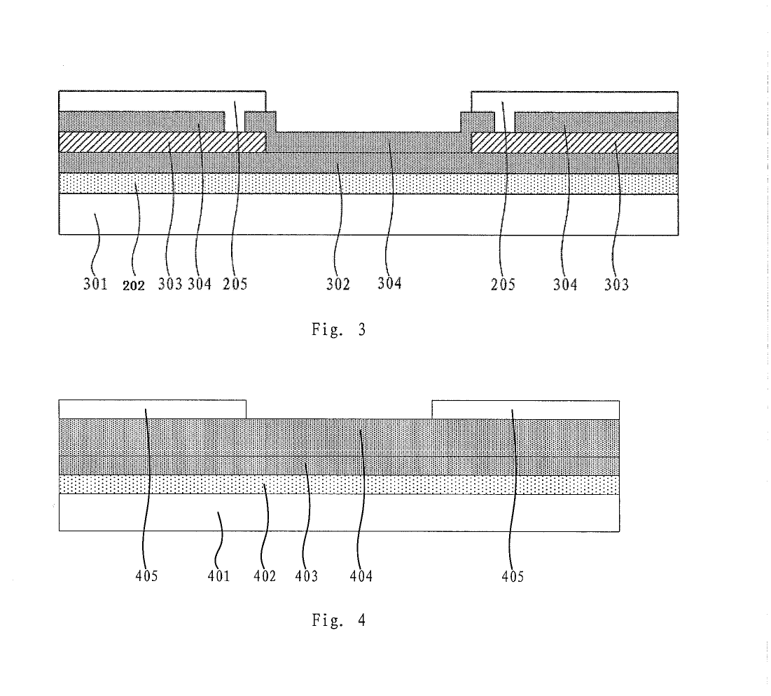

For example, as illustrated in the section of the pixel structure shown in FIG. 2 taken in an A-A′ direction, the specific layer arrangement of the pixel structure of the present embodiment may comprise (see FIG. 3): a substrate 301; common electrodes 202 provided on the substrate 301; a gate insulation layer 302 located over the common electrodes 202; electrically conductive electrodes 303 provided on the gate insulation layer 302; a passivation layer 304 located over the electrically conductive electrodes 303; and pixel electrodes 205 provided on the passivation layer 304.

The electrically conductive electrode 303 is located below an overlapped region between a corresponding pixel electrode 205 and a corresponding common electrode 202. Specifically, the electrically conductive electrode 303 are located between the passivation layer 304 and the gate insulation layer 302 (that is, between a corresponding pixel electrode 205 and a corresponding common electrode 202), and within the overlapped region between the pixel electrode 205 and the common electrode 202.

Shapes and sizes of the electrically conductive electrodes 303 are not limited in this embodiment. Alternatively, if the common electrode 202 are divided into two portions including a first portion overlapped with two pixel electrodes 205 (that is, the first portion is located across two pixel electrodes 205), and a second portion only overlapped with one pixel electrode 205, since an overlapped area between first portion and the pixel electrodes 205 takes a largest proportion in a total overlapped area between the common electrode 202 and pixel electrodes 205, the electrically conductive electrodes 303 may be located within the overlapped regions between the first portion and the pixel electrodes 205; alternatively, considering that the larger the overlapped area is, the larger the capacitance is, the electrically conductive electrodes 303 may be located in the overlapped regions between the first and second portions and the pixel electrodes 205 so as to maximize the overlapped area between the electrically conductive electrodes 303 and the pixel electrodes 205, thereby enabling a larger storage capacitor; further, the electrically conductive electrodes 303 may have completely the same shapes and sizes as those of the common electrodes 202, and be fully overlapped with the common electrodes 20, so that there is a largest overlapped area between the electrically conductive electrodes 303 and the common electrodes 202.

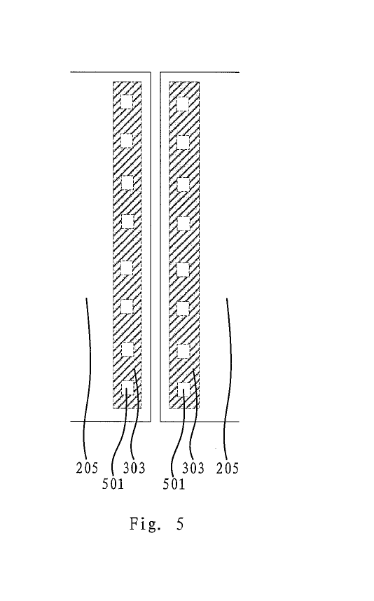

In the pixel structure according to the present embodiment, the manner in which the electrically conductive electrodes 303 are electrically connected with the pixel electrodes 205 is not limited. Alternatively, at least one via hole 501 (see FIG. 5) may be provided in a part of the passivation layer 304 located within the overlapped regions between the pixel electrodes 205 and the common electrodes 202, and the pixel electrodes 205 are electrically connected with the electrically conductive electrodes 303 via the via holes 501.

In order to insure good electrical connection between the electrically conductive electrodes 303 and the pixel electrodes 20, a plurality of via hole 501 may be provided in the passivation layer 304 so as to increase contact area between the electrically conductive electrodes 303 and the pixel electrodes 205 and thus to reduce ohmic contact resistance therebetween. As shown in FIG. 5, below adjacent edges of the two pixel electrodes 205 within the same one grid, the first portion of the common electrode is provided across edges of the two pixel electrodes 205 within the same one grid; in addition, the electrically conductive electrode 303 is provided between a layer in which the first portion is located and another layer in which the two pixel electrodes 205 are located, the passivation layer is located between the electrically conductive electrode 303 and the two pixel electrodes 205. Further, a plurality of via holes 501 are provided in the passivation layer and are alternatively arranged at the same spacing, and the two pixel electrodes 205 provided on the passivation layer are electrically connected with the electrically conductive electrode 303 below the passivation layer via these via holes 501.

Methods of forming the via holes for electrically connecting the pixel electrodes 205 with the electrically conductive electrodes 303 are not limited in the present embodiment. Also formed in the passivation layer 304 are pixel electrode contact holes (not shown, which are similar to the via holes 501 but are located at different positions from the via holes 501) for electrically connecting the drains of the thin film transistors with the pixel electrodes 205 respectively, thus, the via holes for electrically connecting the pixel electrodes 205 with the electrically conductive electrodes 303 and the pixel electrode contact holes may be formed simultaneously without increasing steps of manufacturing the whole pixel structure, thereby simplifying manufacturing process.

In the pixel structure according to the present embodiment, optionally, the electrically conductive electrodes 303 are made of metal material. Optionally, the electrically conductive electrodes 303 are made of the same material as the sources and drains of the thin film transistors, so that the electrically conductive electrodes 303 and the sources and drains may be formed in the same layer without increasing steps of manufacturing the whole pixel structure.

Since in the pixel structure according to the present embodiment, there are an overlapped area between the common electrode 202 and a connection structure between the electrically conductive electrode 303 and the pixel electrode 205, and the connection structure is separated from the common electrode 202 by the gate insulation layer 302, a storage capacitor is formed by the connection structure and the common electrode 202, the storage capacitor is used for maintaining display of previous frame of picture before the display device switches to next frame of picture. The connection structure between the electrically conductive electrode 303 and the pixel electrode 205 corresponds to one electrode plate of the storage capacitor, while the common electrode 202 corresponds to the other electrode plate of the storage capacitor, thus, a distance between the two electrode plates of the storage capacitor in the present embodiment is equal to a film thickness of the gate insulation layer 302.

In a pixel structure of prior arts, however, a distance between two electrode plates of the storage capacitor is equal to a sum of a film thickness of the gate insulation layer and a film thickness of the passivation layer. With reference to FIG. 4, in a process of manufacturing the pixel structure of prior arts, common electrodes 402, gate lines, and gates of thin film transistors are formed on a substrate 401 simultaneously, then a gate insulation layer 403 is formed over a pattern including the common electrodes 402, the gate lines and gates, then data lines, sources and drains of the thin film transistors are formed simultaneously, then a passivation layer 404 is formed over a pattern including the data lines, the source and the drains, and then pixel electrodes 405 are formed on the passivation layer 404. As can be seen from this process, in pixel structure of prior arts, there will necessarily be two film layers, that is, the passivation layer 404 and the gate insulation layer 403, between the pixel electrode 405 and the common electrode 402, a distance between two electrode plates of a storage capacitor formed by overlapped pixel electrode 405 and common electrode 402 (the pixel electrode 405 corresponds to one electrode plate of the storage capacitor, while the common electrode 402 corresponds to the other electrode plate of the storage capacitor) is equal to a sum of a film thickness of the passivation layer 404 and a film thickness of the gate insulation layer 403.

As can be seen from the above, the distance between the two electrode plates of the storage capacitor of the pixel structure according to the present embodiment is smaller than that in prior art. Since capacitance of a capacitor is inversely proportional to a distance of the capacitor's electrode plates, the pixel structure according to the present embodiment provides a larger storage capacitor, which can function to better maintain display of picture so as to improve picture display performance of the display device.

The pixel structure according to the embodiment shown in FIG. 3 may be manufactured by a method comprising following steps: forming a first pattern including common electrodes 202, gate lines, and gates of thin film transistors on a substrate 301 by using a patterning process, wherein the gate lines are electrically connected with the gates respectively; forming a gate insulation layer 302 over the substrate by using a film deposition process after the step of forming the first pattern; forming a second pattern including electrically conductive electrodes 303, data lines, sources and drains of the thin film transistors on the gate insulation layer 302 by using a patterning process, wherein the data lines are electrically connected with the sources respectively; forming a passivation layer 304 over the substrate by using a film deposition process after forming the second pattern, and then forming via holes and pixel electrode contact holes in the passivation layer 304 by using a patterning process; and forming pixel electrodes 205 on the passivation layer, wherein the pixel electrodes 205 are electrically connected with the electrically conductive electrodes 303 via the via holes and are electrically connected with the drains via the pixel electrode contact holes, respectively.

In the above method, the step of forming the common electrodes 202 and the step of forming the gate lines 201 and the gates of the thin film transistors are the same one step, the step of forming the electrically conductive electrodes 303 and the step of forming the data lines 203, and the sources and the drains of the thin film transistors are the same one step, and the step of forming the via holes for electrically connecting the pixel electrodes 205 with the electrically conductive electrodes 303 and the step of forming the pixel electrode contact holes for electrically connecting the pixel electrodes 205 with the drains are the same one step, no additional step needs to be added for manufacturing the pixel structure, and the process is easy to be implemented. On the basis of simplifying manufacturing steps and easy implementation of process, the connection structures between the pixel electrodes 205 and the electrically conductive electrodes 303, and the common electrodes 202 form larger storage capacitors, thereby improving display performance. The pixel structure according to the present embodiment may be a double-gate driven pixel structure, but may be other types of pixel structure in other embodiments of the present invention.

Embodiments of the present invention further provide a display device comprising the display device of the above embodiments. Since the storage capacitor of the pixel structure according to the above embodiments comprises the connection structure between the pixel electrode 205 and the electrically conductive electrode 303, and the common electrode 202, so that the distance between two electrode plates of the storage capacitor is only equal to a film thickness of the gate insulation layer 204, thereby compared to prior art, reducing the distance between the two electrode plates of the storage capacitor, increasing the storage capacitor, and improving the display performance of the display device as a whole.

It is noted that specific type of the display device according to embodiments of the present invention is not limited, for example, the display device may be a liquid crystal display device, and further, may be a twisted nematic type liquid crystal display device.

Although several exemplary embodiments have been shown and described, it would be appreciated by those skilled in the art that various changes or modifications may be made in these embodiments without departing from the principle and spirit of the disclosure, the scope of which is defined in the claims and their equivalents.

What is claimed is:

1. A pixel structure comprising:
thin film transistors;
a substrate, and common electrodes, a gate insulation layer, a passivation layer and pixel electrodes stacked in order on the substrate; and
electrically conductive electrodes located between the passivation layer and the gate insulation layer, the electrically conductive electrodes being located within overlapped regions between the pixel electrodes and the common electrodes and electrically connected with the pixel electrodes, respectively.

2. The pixel structure according to claim 1, wherein
a portion of the passivation layer located within the overlapped regions between the pixel electrodes and the common electrodes has at least one via hole, through which the pixel electrodes are electrically connected with the electrically conductive electrodes.

3. The pixel structure according to claim 2, wherein
the passivation layer is further formed with pixel electrode contact holes therein for electrically connecting drains of the thin film transistors with the pixel electrodes respectively.

4. The pixel structure according to claim 1, wherein
the pixel structure comprises a double-gate driven pixel structure in which two pixel electrodes are provided between two gate lines and two corresponding data lines of the double-gate driven pixel structure.

5. The pixel structure according to claim 4, wherein
each common electrode comprises a first portion overlapped with both of the two pixel electrodes and a second portion only overlapped with one of the two pixel electrodes, and the electrically conductive electrodes are located within overlapped regions between the first portion and the pixel electrodes.

6. The pixel structure according to claim 4, wherein
each common electrode comprises a first portion overlapped with both of the two pixel electrodes and a second portion only overlapped with one of the two pixel electrodes, and the electrically conductive electrode are located within overlapped regions between the first and second portions and the pixel electrodes.

7. The pixel structure according to claim 5, wherein
in a region where the common electrode is overlapped with its corresponding pixel electrode, the shape and size of the electrically conductive electrode are the same as those of the common electrode.

8. The pixel structure according to claim 6, wherein
in a region where the common electrode is overlapped with its corresponding pixel electrode, the shape and size of the electrically conductive electrode are the same as those of the common electrode.

9. The pixel structure according to claim 1, wherein
the electrically conductive electrodes are made of the same material as those of sources and drains of the thin film transistors of the pixel structure.

10. The pixel structure according to claim 9, wherein
the electrically conductive electrodes are arranged in the same layer as the sources and the drains.

11. The pixel structure according to claim 1, wherein
the pixel structure is a double-gate driven pixel structure.

12. A method of manufacturing a pixel structure, comprising following steps:
forming a first pattern including common electrodes, gate lines, and gates of thin film transistors on a substrate by using a patterning process, wherein the gate lines are electrically connected with the gates respectively;
forming a gate insulation layer over the substrate by using a film deposition process after the step of forming the first pattern;
forming a second pattern including electrically conductive electrodes, data lines, sources and drains of the thin film transistors on the gate insulation layer by using a patterning process, wherein the data lines are electrically connected with the sources respectively;
forming a passivation layer over the substrate by using a film deposition process after forming the second pattern, and then forming via holes and pixel electrode contact holes in the passivation layer by using a patterning process; and
forming pixel electrodes on the passivation layer, wherein the pixel electrodes are electrically connected with the electrically conductive electrodes respectively through the via holes and are electrically connected with the drains respectively through the pixel electrode contact holes.

13. A display device, comprising the pixel structure according to claim 1.

14. The display device according to claim 13, wherein
the pixel structure is the pixel structure according to claim 2.

15. The display device according to claim 13, wherein
the pixel structure is the pixel structure according to claim 3.

16. The display device according to claim 13, wherein
the pixel structure is the pixel structure according to claim 4.

17. The display device according to claim 13, wherein
the pixel structure is the pixel structure according to claim 8.

18. The display device according to claim 13, wherein
the pixel structure is the pixel structure according to claim 9.

19. The display device according to claim 13, wherein
the pixel structure is the pixel structure according to claim 10.

20. The display device according to claim 13, wherein
the pixel structure is the pixel structure according to claim 11.
